(19) United States
(12) Patent Application Publication
(10) Pub. No.: US 2026/0040907 A1
(43) Pub. Date: Feb. 5, 2026

(54) METHOD FOR MANUFACTURING A SUPPORT SUBSTRATE FOR A RADIOFREQUENCY APPLICATION

(71) Applicant: Soitec, BERNIN (FR)

(72) Inventors: Young-Pil Kim, BERNIN (FR); Chee-Hoe Wong, Bernin (FR)

(21) Appl. No.: 19/472,475

(22) PCT Filed: Jul. 18, 2023
(86) PCT No.: PCT/FR2023/051108

§ 371 Date: Oct. 3, 2025

(30) Foreign Application Priority Data
Jul. 19, 2022 (FR) FR2207362
Oct. 5, 2022 (FR) FR2210185

(51) Int. Cl. H01L 21/762; H01L 21/02; H10N 30/079

(52) U.S. Cl. CPC H01L 21/76254; H01L 21/02238; H10N 30/079

(57) ABSTRACT

A method for manufacturing a support substrate comprising a charge-trapping layer for a semiconductor-on-insulator or piezoelectric-on-insulator structure for a radio-frequency application, includes: placing a base substrate comprising a layer of native silicon oxide in a deposition chamber; raising the temperature of the deposition chamber to a deposition temperature of the charge-trapping layer; introducing an oxidizing gas into the deposition chamber in order to preserve the layer of native silicon oxide during the temperature rise; venting the oxygen from the deposition chamber at the formation temperature of the charge-trapping layer; and-depositing, in the deposition chamber, the charge-trapping layer of polycrystalline silicon on the layer of native silicon oxide.

### CROSS-REFERENCE TO RELATED APPLICATIONS

This application is a national phase entry under 35 U.S.C. § 371 of International Patent Application PCT/FR2023/051108, filed Jul. 18, 2023, designating the United States of America and published as International Patent Publication WO 2024/018149 A1 on Jan. 25, 2024, which claims the benefit under Article 8 of the Patent Cooperation Treaty of French Patent Application Serial No. FR2207362, filed Jul. 19, 2022 and French Patent Application Serial No. FR2210185, filed Oct. 5, 2022.

### TECHNICAL FIELD

The present disclosure relates to a process for preparing a carrier substrate for production of a semiconductor-on-insulator or piezoelectric-on-insulator structure, the carrier substrate comprising an oxide layer and a charge-trapping layer. The present disclosure also relates to such a carrier substrate.

### BACKGROUND

These carrier substrates are, in particular, applicable to the field of integrated radio-frequency devices, i.e., electronic devices that process signals in the frequency range between about 3 kHz and 300 GHz, for example, in the field of telecommunications (telephony, Wi-Fi, BLUETOOTH®, etc.).

An SOI or POI substrate (SOI standing for semiconductor-on-insulator and POI standing for piezoelectric-on-insulator, respectively) such as used for radio-frequency applications comprises, in succession, a carrier substrate, a buried oxide layer (often referred to by the acronym BOX, for Buried OXide) and a single-crystal semiconductor or piezoelectric layer, respectively, which is the active layer, i.e., the layer in or on which electronic components are intended to be formed.

In order to avoid or limit the effect of electromagnetic coupling that may occur between an electronic device and the carrier substrate of a silicon-on-insulator substrate on which the device is formed, it is known practice to integrate a layer of polysilicon (polycrystalline silicon) into the carrier substrate, directly under the buried oxide layer. Traps for charge carriers are created at the boundaries of the grains forming the polycrystal. Thus, formation of a conductive plane under the insulation is prevented.

Before the trapping layer is formed, it is known practice to form a passivation layer on the carrier substrate. Such a layer promotes formation of the trapping layer and prevents its recrystallization, in particular, during increases in the temperature of the substrate. The passivation layer is made of an amorphous dielectric, typically silicon dioxide.

FIGS. 1A to 1C illustrate fabrication of a known carrier substrate. Typically, with reference to FIG. 1A, the passivation layer 21 is formed by oxidizing the base substrate 10 by delivering an oxidizing gas 40 to an enclosure at a temperature above 1000° C. Next, with reference to FIG. 1B, without withdrawing the substrate comprising the passivation layer from the enclosure, the oxidizing gas is removed. With reference to FIG. 1C, the charge-trapping layer 30 is formed in the same enclosure.

With reference to FIG. 2, such a process requires a first annealing phase in the interval between tc1 and tc2 aiming to completely degrade the native oxide layer that naturally forms on the substrate during contact with ambient air before the deposition of other layers. The process further comprises an oxidizing phase between tc2 and tc3 and a phase between tc3 and tc4 of removing the oxidizing gas before the charge-trapping layer is produced between tc4 and tc5. The process ends at tc6 after cooling of the carrier substrate. All these steps are typically carried out at a high temperature Tₚ above 1000° C., and typically at the same temperature as the deposition of the charge-trapping layer. Such a process is lengthy and therefore involves consumption of a lot of power and unavailability of the deposition chamber.

U.S. Patent Application Publication No. 2003/0097977 A1 provides another process for fabricating such a substrate. In this process, on a base substrate, a layer having the same crystal qualities as the base substrate is formed by epitaxy. Subsequently, a reagent is introduced into the epitaxy chamber in order to convert the epitaxial layer into an oxide layer. Such deposition and oxidation steps are complex and increase the time required to fabricate the substrate.

### BRIEF SUMMARY

One aim of the present disclosure is to provide a simpler and faster process for fabricating a carrier substrate comprising a passivation layer and a charge-trapping layer.

To this end, the present disclosure provides a process for fabricating a carrier substrate comprising a charge-trapping layer for a semiconductor-on-insulator or piezoelectric-on-insulator structure for radio-frequency applications, comprising:
placing a base substrate comprising a layer of native silicon oxide in a deposition chamber,
increasing the temperature of the deposition chamber to a deposition temperature of the charge-trapping layer,
introducing an oxidizing gas into the deposition chamber, with a view to preserving the layer of native silicon oxide during the increase in temperature,
removing oxygen from the deposition chamber at the temperature of formation of the charge-trapping layer,
depositing, in the deposition chamber, the polycrystalline silicon charge-trapping layer on the layer of native silicon oxide.

Delivering an oxidizing gas to the chamber allows the native oxide layer to be preserved, in order to form the layer of polycrystalline silicon directly on this layer, without having to deposit a new layer of silicon oxide. Therefore, the length of the high-temperature process is decreased. This makes it possible to save heating energy and to more rapidly reuse the enclosure to fabricate other substrates.

In certain embodiments, the process further comprises forming a second layer of silicon oxide between the first layer of native silicon oxide and the base substrate.

Preferably, the total thickness of the one or more layers of silicon oxide is between 0.5 and 1.5 nm.

The time that elapses between the end of oxygen removal and the start of the deposition of the charge-trapping layer is greater than 30 seconds.

Preferably, the deposition temperature of the charge-trapping layer is above 950° C.

Advantageously, the oxidizing gas comprises oxygen or a mixture of argon and oxygen.

Advantageously, the base substrate is made of single-crystal silicon. Preferably, the charge-trapping layer is made of polycrystalline silicon.

In certain embodiments, the charge-trapping layer is formed using a chemical-vapor-deposition process.

The present disclosure also relates to a process for fabricating a semiconductor-on-insulator structure for radio-frequency applications, characterized in that it comprises the following steps:
fabricating a carrier substrate using a process such as described above,
providing a semiconductor or piezoelectric donor substrate,
forming an electrically insulating layer on the charge-trapping layer and/or on the donor substrate,
bonding the donor substrate to the carrier substrate via the electrically insulating layer,
transferring the semiconductor or piezoelectric layer to the carrier substrate, the electrically insulating layer being arranged at the interface between the transferred semiconductor or piezoelectric layer and the charge-trapping layer.

In certain embodiments, the process further comprises a step of forming a weakened region in the donor substrate so as to define a semiconductor or piezoelectric layer to be transferred, and transferring the semiconductor or piezoelectric layer to the carrier substrate comprises detaching the donor substrate along the weakened region.

In certain embodiments, the process may comprise, before the step of forming the weakened region in the donor substrate, a step of bonding the donor substrate to a temporary substrate so as to form what is referred to as a pseudo-donor substrate, and the bonding step then comprises bonding the pseudo-donor substrate to the carrier substrate via the electrically insulating layer.

In other embodiments, transferring the semiconductor or piezoelectric layer to the carrier substrate comprises thinning the donor substrate from the side opposite the electrically insulating layer.

In certain applications, the donor substrate is semiconductor and comprises silicon.

In other applications, the donor substrate is piezoelectric and comprises a compound of formula ABO3, where A is selected from barium and lithium and B is selected from tantalum, titanium and niobium.

### BRIEF DESCRIPTION OF THE DRAWINGS

Other features and advantages of the present disclosure will become apparent on reading the following detailed description, with reference to the appended drawings, in which:

FIG. 1A illustrates a known process for fabricating a passivation layer.

FIG. 1B illustrates a carrier substrate comprising a passivation layer fabricated in the process of FIG. 1A.

FIG. 2 is the temperature profile of a known process for fabricating a carrier substrate.

FIG. 3A and FIG. 3B illustrate a process for fabricating a passivation layer according to the present disclosure.

FIG. 3C illustrates a carrier substrate comprising a passivation layer.

FIG. 4 shows the reaction rate as a function of temperature.

FIG. 5 illustrates a process for fabricating a passivation layer according to a second embodiment.

FIG. 6 shows the thickness of silicon oxide formed as a function of temperature.

FIG. 7 is the temperature profile of a known process for fabricating a carrier substrate and of a process according to the present disclosure.

FIGS. 8A to 8E illustrate a first process for fabricating a semiconductor-on-insulator or piezoelectric-on-insulator substrate using a carrier substrate according to the present disclosure.

FIGS. 9A to 9D illustrate one variant of embodiment of the process of FIGS. 8A to 8E, implementing formation of a pseudo-donor substrate.

FIGS. 10A to 10C illustrate a second process for fabricating a semiconductor-on-insulator or piezoelectric-on-insulator substrate using a carrier substrate according to the present disclosure.

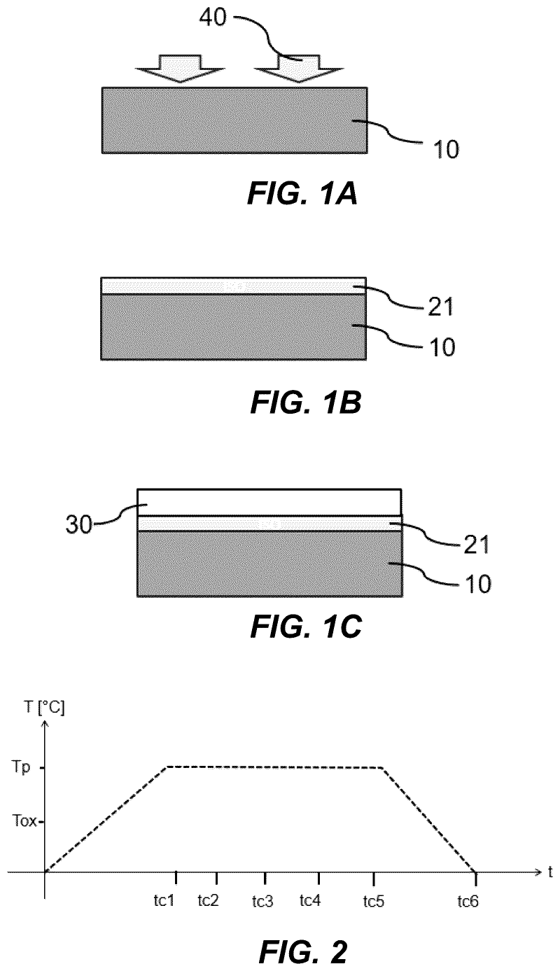

### DETAILED DESCRIPTION

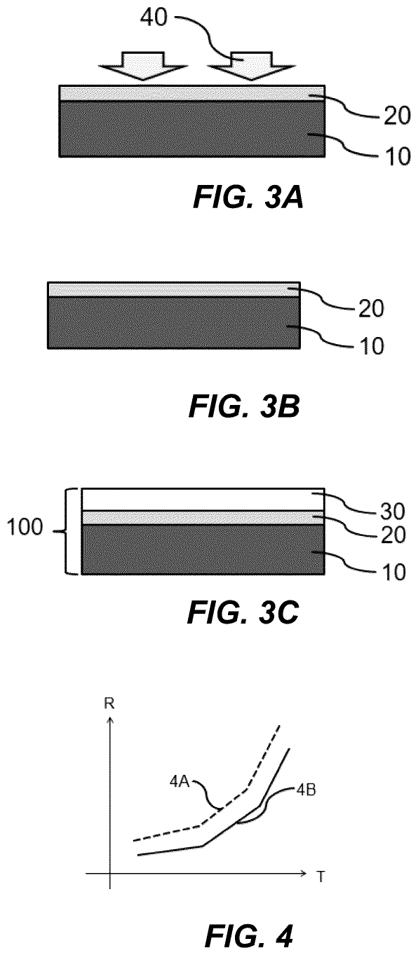

FIGS. 3A to 3C show fabrication of a carrier substrate 100 (FIG. 3C) according to a first embodiment of the present disclosure. With reference to FIG. 3A, the process starts with provision of a base substrate 10 that comprises a layer 20 of native silicon oxide. Typically, this substrate may be made of single-crystal silicon. Such a layer 20 of native oxide forms during contact with oxygen-containing air after fabrication of the base substrate 10, for example, after it has been cut from an ingot. This layer of native oxide is therefore present on any silicon substrate exposed to ambient air. The thickness of the layer 20 of native silicon oxide is typically between 0.5 and 1 nm.

The base substrate 10 with the layer 20 of native oxide is placed in a deposition chamber suitable for depositing a charge-trapping layer 30. Such an enclosure is typically a CVD deposition chamber (CVD being the acronym of chemical vapor deposition). However, the present disclosure is not limited to a process carried out in a CVD enclosure and a charge-trapping layer 30 deposited by CVD. The process is applicable to a base substrate 10 on which a charge-trapping layer 30 is deposited by any technique requiring an increase in temperature liable to degrade the layer 20 of native silicon oxide present on the base substrate 10.

The base substrate 10 comprising the layer 20 of native oxide is gradually heated from room temperature, which is typically close to 20° C., to a deposition temperature Tₚ of the charge-trapping layer. This temperature Tₚ is typically above 950° C.

During the heating, external gases that may have been introduced into the deposition chamber during introduction of the base substrate are removed. An oxidizing gas 40 is then introduced into the deposition chamber to preserve the layer 20 of native silicon oxide during the increase in temperature. Such an oxidizing gas 40 may be oxygen (O₂) or a mixture of an inert carrier gas with oxygen, a mixture of argon and oxygen, for example. The introduction of the oxidizing gas 40 into the chamber is started at a temperature Tₒₓ between 700 and 950° C. to avoid the degradation of the layer 20 of native silicon oxide that occurs at higher temperatures. The oxygen flow ensures preservation of the layer 20 of native silicon oxide during the increase in temperature to the deposition temperature Tₚ of the charge-trapping layer 30. The layer 20 of native silicon oxide therefore remains in place on the surface of the base substrate 10 and may be used as a passivation layer between the base substrate 10 and a charge-trapping layer 30.

During stabilization of the temperature at the deposition temperature Tₚ, and before a charge-trapping layer 30 is formed, the oxidizing gas 40 is removed from the deposition chamber. From removal of the oxidizing gas 40, the layer 20 of native silicon oxide begins to degrade due to the high temperature to which the layer is exposed. The charge-trapping layer 30 is therefore deposited rapidly after the removal of the oxidizing gas. However, it is necessary to ensure thorough removal of oxygen and a stabilization of the temperature Tₚ, for the deposition of the charge-trapping layer 30. The delay between complete removal of the oxidizing gas 40 and the start of formation of the charge-trapping layer 30 is advantageously between 5 and 100 seconds to avoid excessive degradation of the layer 20 of native silicon oxide.

With reference to FIG. 3C, the charge-trapping layer 30 is formed in the same enclosure. The charge-trapping layer 30 is typically made of polycrystalline silicon. This layer is typically deposited using a CVD process (CVD standing for chemical vapor deposition).

After deposition of the charge-trapping layer 30, production of the carrier substrate 100 is completed and it may be used to produce a semiconductor-on-insulator structure.

FIG. 4 shows the reaction rate R as a function of temperature during the same step of increasing temperature while oxidizing gas is delivered, which step is carried out in the time between t1 and t2 as illustrated in FIG.7. The curve 4A indicates the oxidation rate of the single-crystal silicon of the base substrate due to the flow of oxidizing gas introduced into the deposition chamber (this oxidation rate induces an increase in the thickness of the layer of silicon oxide). The curve 4B corresponds to the degradation of the oxide layer due to the increase in temperature (this degradation rate induces a decrease in the thickness of the layer of silicon oxide). The two curves vary in parallel. Thus, the two competing effects mutually counteract, thus ensuring the thickness of the layer of silicon oxide on the base substrate remains stable. The layer of native oxide is preserved during this process.

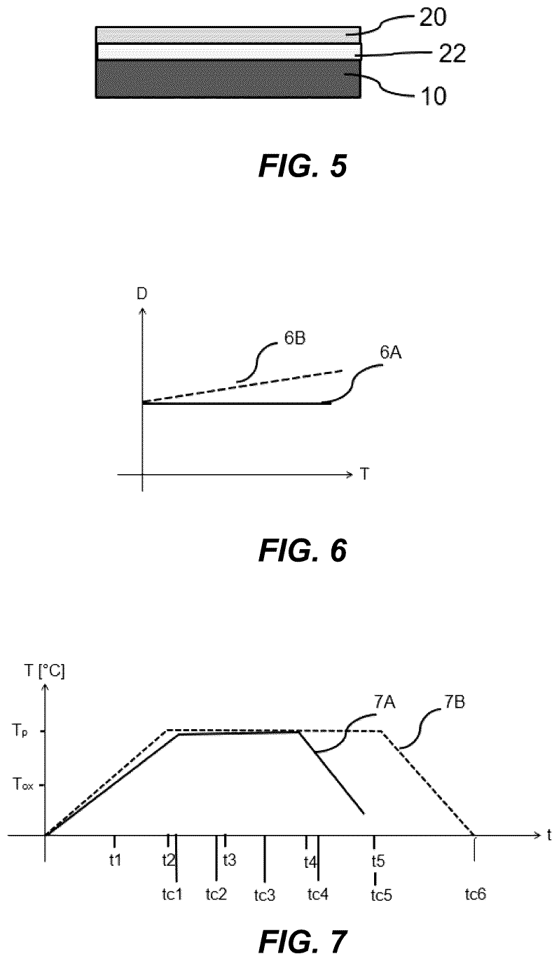

A second embodiment is illustrated in FIG. 5. Elements designated by the same reference signs as in FIGS. 3A to 3C are identical to or perform the same function as those elements already described in respect of the first embodiment, and will therefore not be described again.

A base substrate 10 comprising a layer 20 of native silicon oxide is provided. The base substrate 10 is heated in a deposition chamber under a flow of an oxidizing gas 40. The flow rate and oxygen concentration of the oxidizing gas 40 are selected so that the amount of oxygen delivered is greater than in the first case. This makes it possible to promote the oxidation effect over and above the effect of degradation of the oxide layer. Thus, delivering a sufficiently high amount of oxygen makes it possible not only to preserve the layer 20 of native silicon oxide but also to cause formation of an additional layer 22 of silicon oxide at the interface between the base substrate 10 and the layer 20 of native oxide. This additional layer 22 is produced by oxidizing some of the silicon on the surface of the base substrate 10, below the layer 20 of native silicon oxide. The initial layer of native silicon oxide is thus thickened by an additional layer 22, to obtain a larger total thickness of silicon oxide.

The passivation layer is thus composed of a segment 20 made of native silicon oxide and of a segment 22 made of silicon oxide formed by oxidation during the increase in temperature in a flow of oxidizing gas 40. Such a passivation layer has a total thickness between 0.6 and 1.6 nm.

The oxidizing gas 40 is then removed in the same way as in the embodiment described above, during the phase of stabilization of the deposition temperature Tₚ of the charge-trapping layer 30. The charge-trapping layer 30 is deposited after stabilization of the temperature Tₚ and complete removal of the oxidizing gas 40.

This second embodiment is particularly suitable when the layer 20 of native oxide is relatively thin or when part of the passivation layer runs the risk of undergoing degradation before the deposition of the charge-trapping layer.

FIG. 6 illustrates the total thickness D of the oxide layer on the base substrate during fabrication of the carrier substrate as a function of the temperature T during the increase in temperature. In the first embodiment, with reference to curve 6A, the thickness of the oxide layer remains substantially constant. This thickness corresponds to the thickness of the layer of native silicon oxide present on the base substrate. In the second embodiment, with reference to curve 6B, the thickness of the layer is equal to the thickness of the layer of native oxide at the start of the process, at the time of introduction of the oxidizing gas into the deposition chamber. The thickness of the layer of native oxide also remains substantially constant during this process. In parallel, the additional layer 22 is formed via oxidation of some of the silicon on the surface of the base substrate. The thickness of the additional layer 22 increases linearly. This thickness is added to the thickness of the native oxide layer already present on the base substrate.

### Change in the Base Substrate Over Time

FIG. 7 shows the temperature profile 7A of a process according to the present disclosure in comparison with the temperature profile 7B of a known process for fabricating a carrier substrate. The profile 7B is identical to the profile of a known process illustrated in FIG. 2. In the process according to the present disclosure, with reference to profile 7A, the oxidizing gas 40 is introduced into the furnace at the time t1 at the temperature Tₒₓ. At the time t2, the deposition temperature Tₚ of the charge-trapping layer is reached. In the interval between t2 and t3, the oxidizing gas 40 is removed from the deposition chamber. Deposition of the charge-trapping layer then begins, and thereafter ends at t4. After cooling, at t5, production of the carrier substrate is completed and it may be withdrawn from the deposition chamber. In the known process, with reference to profile 7B, deposition of the charge-trapping layer ends at tc5 as described above. The time t5 corresponds to the time tc5 at which deposition of the charge-trapping layer begins in a known process.

Compared to the known process, the process according to the present disclosure may be completed in 70% to 85% of the time. Moreover, the oxidizing phase is carried out at a lower temperature and at a lower oxygen flow rate than in the known process. This causes less degradation inside the enclosure.

### Fabrication of a Semiconductor-on-Insulator or Piezoelectric-on-Insulator Structure

The steps carried out to produce a semiconductor-on-insulator or piezoelectric-on-insulator structure for radio-frequency applications will now be described. Such a structure comprises a carrier substrate produced according to a process such as described above, a semiconductor or piezoelectric layer on its surface, and an electrically insulating layer that is disposed at the interface between the carrier substrate and the semiconductor or piezoelectric surface layer.

Fabrication of such a structure typically involves joining a semiconductor or piezoelectric donor substrate to the carrier substrate, the electrically insulating layer being disposed at the interface between the two substrates, and transferring a semiconductor or piezoelectric layer from the donor substrate to the carrier substrate. Various layer-transferring processes may be employed.

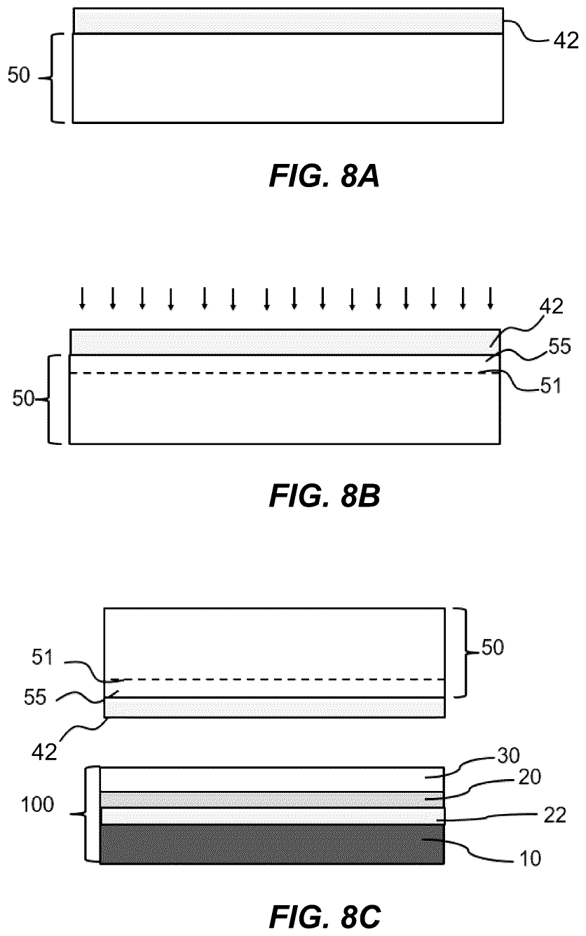

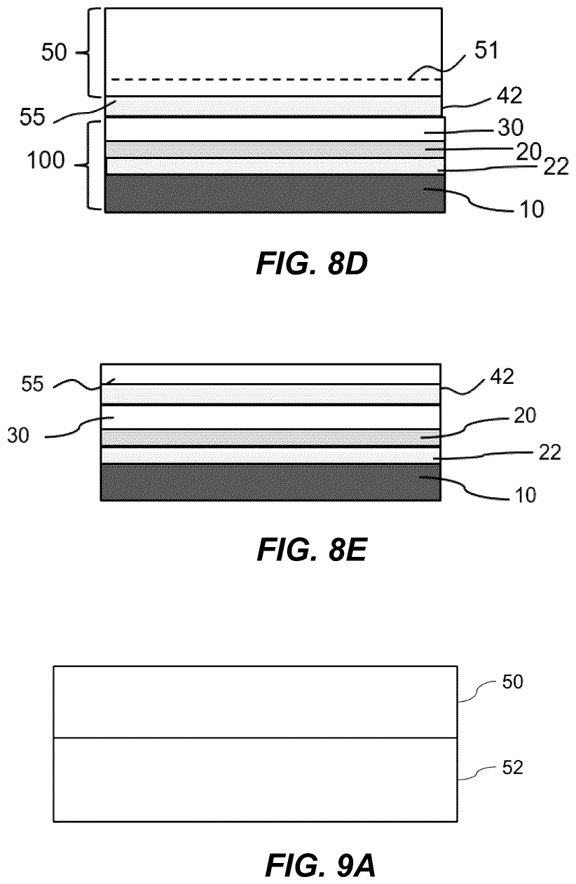

FIGS. 8A-8E schematically illustrate steps of a first form of execution of the process for fabricating the structure, using the so-called Smart Cut™ process.

With reference to FIG. 8A, the first step is to provide a semiconductor donor substrate 50 from which a semiconductor layer 55 will be transferred to the carrier substrate 100. The semiconductor of the donor substrate is advantageously silicon. An electrically insulating layer 42 is formed on the surface of the donor substrate 50.

With reference to FIG. 8B, as schematically shown by the arrows, ion species, such as hydrogen and/or helium ions, are implanted through the electrically insulating layer 42, to form a weakened region 51 in the donor substrate 50. The weakened region 51 defines the semiconductor layer 55 to be transferred.

With reference to FIG. 8C and FIG. 8D, the donor substrate 50 thus implanted is bonded to the charge-trapping layer 30 of the carrier substrate 100 via the electrically insulating layer 42. The insulating layer 42 then becomes a buried oxide layer 42.

Alternatively, the electrically insulating layer 42 may be formed on the carrier substrate 100, and the donor substrate 50 comprising the weakened region 51 may be bonded to the carrier substrate 100 comprising the electrically insulating layer 42.

With reference to FIG. 8E, the donor substrate 50 is detached along the weakened region 51, resulting in the semiconductor layer 55 being transferred to the carrier substrate 100, the electrically insulating layer 42 being disposed between the carrier substrate 100 and the semiconductor layer 55. A finishing treatment may subsequently be applied to the transferred layer 55 to heal defects related to the implantation and to smooth the free surface of said the semiconductor layer 55. The semiconductor-on-insulator structure thus obtained may be used to fabricate components for radio-frequency applications.

The steps described above apply in a similar way to the formation of a piezoelectric-on-insulator structure. In this case, the donor substrate comprises at least one segment made of a piezoelectric from which the layer to be transferred is taken.

The piezoelectric is advantageously selected from compounds of formula ABO₃, where A is selected from barium and lithium and B is selected from titanium, tantalum and niobium (for example, lithium niobate (LiNbO₃), lithium tantalate (LiTaO₃), or barium titanate (BaTiO₃)). Other piezoelectric materials usable in the present disclosure are, non-limitingly, potassium sodium niobate (KₓNa₁₋ₓNbO₃ with 0<x<1, or KNN), quartz, lead zirconate titanate (PZT), a compound of lead magnesium niobate-lead titanate (PMN-PT), zinc oxide (ZnO), aluminum nitride (AlN) or aluminum scandium nitride (AlScN).

In certain situations, it is not possible to directly transfer a layer from the donor substrate to the carrier substrate, in particular, because of strains due to the Smart Cut™M process. More particularly, to obtain detachment from the donor substrate along the weakened region, it is generally necessary to carry out an anneal in a temperature range from 100° C. to 600° C. When the donor substrate and the carrier substrate have different coefficients of thermal expansion-this, for example, being the case between a donor substrate made of a piezoelectric and a carrier substrate mainly made of silicon-the anneal results in significant bowing of the assembly consisting of the two substrates, which is detrimental to the transfer in so far that it may lead to breakage of the substrates.

To minimize such bowing, it is possible to form an intermediate substrate called a pseudo-donor substrate, in which the donor substrate is joined to a temporary substrate.

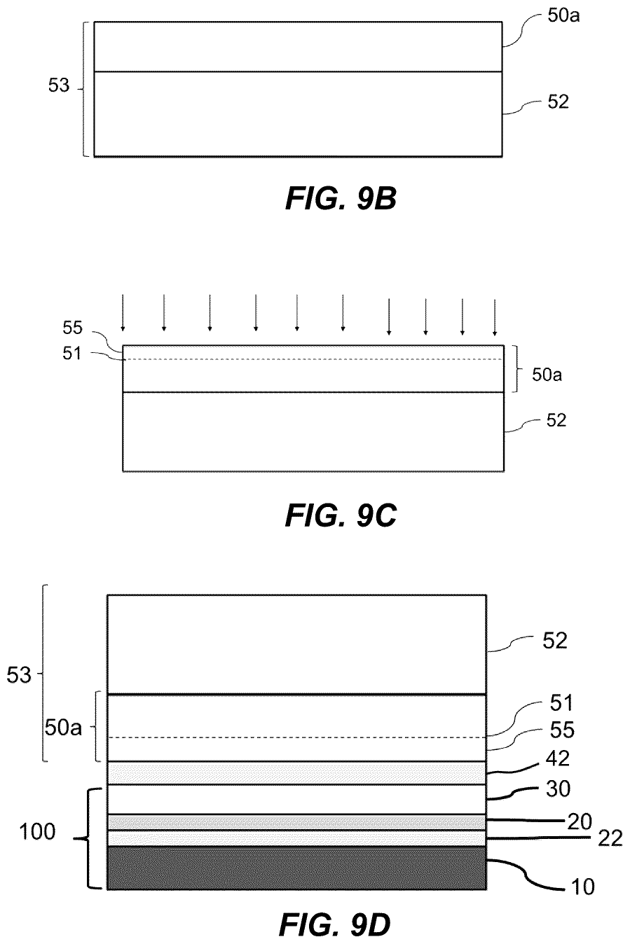

As illustrated in FIGS. 9A-9D, the process for fabricating the POI or SOI structure then comprises a prior step of forming a pseudo-donor substrate 52, by bonding the donor substrate 50 to a temporary pseudo-donor substrate 52 (cf. FIG. 9A), and an optional step of thinning the donor substrate 50 (cf. FIG. 9B). The donor substrate may be bonded to the temporary substrate by direct bonding or via a polymeric layer such as described in document WO 2019/186032, to which the reader may refer for a description of the process for forming the polymeric layer.

With reference to FIG. 9C, a step of implanting atomic species is carried out on the pseudo-donor substrate 53 thus obtained, to form a weakened region 51 defining the layer 55 to be transferred within the thinned donor substrate 50a.

Next, as illustrated in FIG. 9D, the donor pseudo-substrate is bonded to the carrier substrate 100, an electrically insulating layer 42 being arranged at the bonding interface, then a step of detaching the donor pseudo-substrate along the weakened region 51 is implemented to transfer the layer 55 to the carrier substrate 100. The structure already illustrated in FIG. 8E is then obtained.

Particularly advantageously, the temporary substrate has a coefficient of thermal expansion close to that of the carrier substrate, i.e., typically a difference in coefficient of thermal expansion of zero or in absolute value less than 5%. For example, the temporary substrate may be made of silicon. Thus, during the anneal carried out to detach the donor substrate along the weakened region, the two substrates located on either side of the donor substrate bow with a substantially identical amplitude, this avoiding bowing the join.

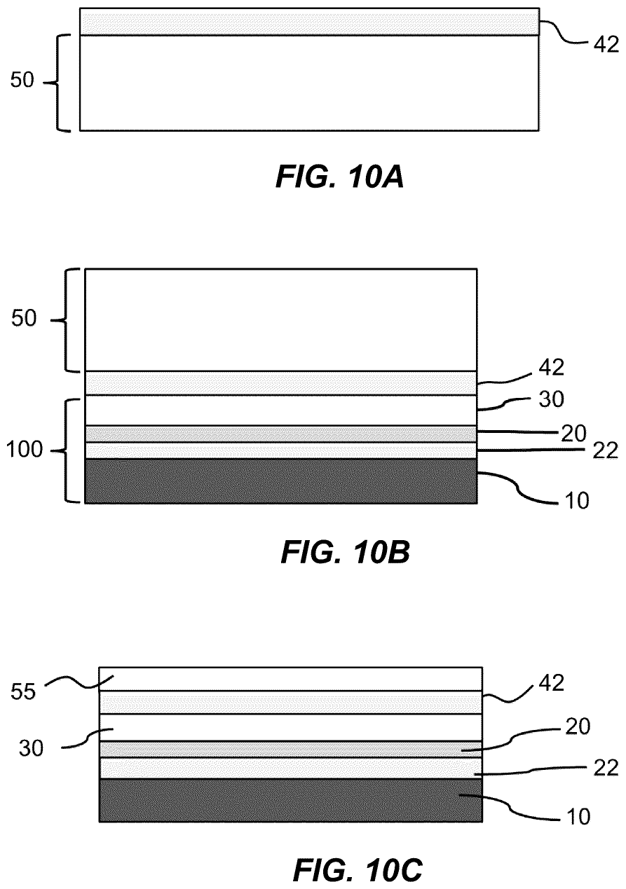

FIGS. 10A-10C schematically illustrate steps of a second form of execution of the process for fabricating the structure, in particular, with a view to fabricating a piezoelectric-on-insulator structure.

With reference to FIG. 10A, a donor substrate 50 is provided from which a layer 55 will be transferred to the carrier substrate 100. An electrically insulating layer 42 is formed on the surface of the donor substrate 50.

With reference to FIG. 10B, the donor substrate 50 is bonded to the charge-trapping layer 30 of the carrier substrate 100 via the electrically insulating layer 42. The latter then becomes a buried oxide layer 42.

Alternatively, the electrically insulating layer 42 may be formed on the carrier substrate 100, and the donor substrate 50 may be bonded to the carrier substrate 100, which comprises the electrically insulating layer 42.

With reference to FIG. 10C, the donor substrate 50 is thinned from its side opposite the bonding interface, for example, by grinding, until the thickness desired for the layer 55 is reached. The layer 55 is thus transferred to the carrier substrate 100, the electrically insulating layer 42 being arranged between the carrier substrate 100 and the semiconductor layer 55. A finishing treatment may subsequently be applied to the transferred layer 55—for example, the free surface of said the semiconductor layer 55 may be polished. The structure thus obtained may be used to fabricate components for radio-frequency applications.

### REFERENCES

US 2003/0097977 A1

1. A method of fabricating a carrier substrate including a charge-trapping layer for a semiconductor-on-insulator or piezoelectric-on-insulator structure for radio-frequency applications, the method comprising:
placing a base substrate comprising a first layer of native silicon oxide in a deposition chamber;
increasing the temperature of the deposition chamber to a deposition temperature of the charge-trapping layer;
introducing an oxidizing gas into the deposition chamber preserving the first layer of native silicon oxide during the increase in temperature;
removing oxygen from the deposition chamber at the temperature of formation of the charge-trapping layer; and
depositing, in the deposition chamber, the charge-trapping layer on the first layer of native silicon oxide.

2. The method of claim 1, further comprising forming a second layer of silicon oxide between the first layer of native silicon oxide and the base substrate.

3. The method of claim 2, wherein a total thickness of the silicon oxide of the first layer of native silicon oxide and the second layer of silicon oxide is between 0.5 and 1.5 nm.

4. The method of claim 3, wherein a time that elapses between the end of oxygen removal and the start of the deposition of the charge-trapping layer is greater than 30 seconds.

5. The process as claimed in any of the preceding claims method of claim 4, wherein the deposition temperature of the charge-trapping layer is above 950° C.

6. The method of claim 5, wherein the oxidizing gas comprises oxygen or a mixture of argon and oxygen.

7. The method of claim 1, wherein the base substrate is made of single-crystal silicon.

8. The method of claim 1, wherein the charge-trapping layer is made of polycrystalline silicon.

9. The method of claim 1, wherein the charge-trapping layer is formed using a chemical vapor deposition (CVD) process.

10. A method of fabricating a semiconductor-on-insulator or piezoelectric-on-insulator structure for radio-frequency applications, comprising:
fabricating a carrier substrate using a process according to claim 1;
providing a semiconductor or piezoelectric donor substrate;
forming an electrically insulating layer on the charge-trapping layer and/or on the donor substrate;
bonding the donor substrate to the carrier substrate via the electrically insulating layer; and
transferring the semiconductor or piezoelectric layer to the carrier substrate, the electrically insulating layer being disposed at the interface between the transferred semiconductor or piezoelectric layer and the charge-trapping layer.

11. The method of claim 10, further comprising forming a weakened region in the donor substrate to define a semiconductor or piezoelectric layer to be transferred, and wherein transferring the semiconductor or piezoelectric layer to the carrier substrate comprises detaching the donor substrate along the weakened region.

12. The process as claimed in method of claim 11, further comprising, before the forming the weakened region in the donor substrate, bonding the donor substrate to a temporary substrate to form a pseudo-donor substrate, and wherein the bonding the donor substrate to the carrier substrate comprises bonding the pseudo-donor substrate to the carrier substrate via the electrically insulating layer.

13. The method of claim 10, wherein the transferring the semiconductor or piezoelectric layer to the carrier substrate comprises thinning the donor substrate from a side of the donor substrate_opposite the electrically insulating layer.

14. The method of claim 10, wherein the donor substrate comprises silicon.

15. The method of claim 10, wherein the donor substrate is piezoelectric and comprises a compound of formula ABO₃, where A is selected from barium and lithium and B is selected from tantalum, titanium and niobium.

16. The method of claim 1, wherein the depositing the charge-trapping layer comprises depositing a polycrystalline silicon charge-trapping layer.

17. The method of claim 2, wherein a total thickness of the first layer of native silicon oxide is between 0.5 and 1.5 nm.

18. The method of claim 1, wherein a time that elapses between the end of oxygen removal and the start of the deposition of the charge-trapping layer is greater than 30 seconds.

19. The method of claim 1, wherein the deposition temperature of the charge-trapping layer is above 950° C.

20. The method of claim 1, wherein the oxidizing gas comprises oxygen or a mixture of argon and oxygen.
